(19) United States
(12) Patent Application Publication
(10) Pub. No.: US 2008/0303111 A1
(43) Pub. Date: Dec. 11, 2008

(54) Sensor package and method for fabricating the same

(75) Inventors: Chang-Yueh Chan, Taichung (TW); Chien-Ping Huang, Taichung Hsien (TW); Tse-Wen Chang, Taichung Hsien (TW); Chih-Ming Huang, Hsinchu Hsein (TW); Cheng-Hsu Hsiao, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/156,901

(22) Filed: Jun. 5, 2008

(30) Foreign Application Priority Data
Jun. 8, 2007 (TW) 096120673

(51) Int. Cl. H01L 31/0203; H01L 31/18

(52) U.S. Cl. 257/434; 438/64; 257/E31.11

(57) ABSTRACT

The invention discloses a sensor package and a method for fabricating the same. The sensor package includes: a substrate with an opening; a sensor chip disposed in the opening and electrically connected to the substrate; an encapsulant filling spacing between the sensor chip and the opening so as to secure the sensor chip to the substrate; and a transparent cover attached to the substrate via an adhesive layer, wherein the adhesive layer covers the sensor chip and bonding wires and is formed with an opening for exposing sensor region of the sensor chip. Securing the sensor chip in the opening of the substrate reduces the height of the sensor package, and meanwhile the process cost is reduced by eliminating the need of formation of conductive bumps on the sensor chip or the transparent cover and eliminating the need of specially designed substrate.

### BACKGROUND OF THE INVENTION

1. Field of the Invention

The present invention relates generally to a semiconductor package and a method for fabricating the same, and more particularly to a sensor package having sensor chip and a method for fabricating the same.

2. Description of Related Art

In a conventional image sensor package, a sensor chip is mounted to a chip carrier and electrically connected to the chip carrier via bonding wires, and a glass cover is provided above the sensor chip so as to prevent water and dust from entering and meanwhile allow image light to be captured by the sensor chip. The image sensor package can be integrated to external devices such as printed circuit boards (PCBs) so as to be applied in various electronic products such as digital cameras, digital videos, optical mice, mobile phones, finger printer scanners and so on.

FIG. 1 is a diagram showing a sensor package and a method for fabricating the same according to U.S. Pat. No. 6,262,479. Referring to FIG. 1, a substrate 10 having an electrically connecting region 10a is provided; a dam structure 12 is formed on the substrate 10, enclosing a space 12a; a sensor chip 11 having a sensor region 11a is received in the space 12a and electrically connected to the electrically connecting region 10a of the substrate 10 via bonding wires 10b; a transparent cover 13 is adhered to the dam structure 12 to seal the space 12a, thereby isolating the sensor chip 11 and the bonding wires 10b from the surrounding atmosphere and meanwhile allowing the light to be captured by the sensor region 11a of the sensor chip 11.

However, the dam structure 12 is required to have a height higher than height of the sensor chip 11 plus the bonding wires 10b such that the sensor chip 11 and the bonding wires 10b can be received in the space 12a. As a result, it becomes difficult to reduce height of the whole sensor package so as to meet demand for thinner sensor packages.

Accordingly, U.S. Pat. No. 6,995,462 discloses another sensor package and a method for fabricating the same, as shown in FIGS. 2A to 2D. Referring to FIG. 2A, a transparent plate 230 having a plurality of dam structures 22 made of such as an adhesive is cut so as to form a plurality of transparent covers 23. Meanwhile, as shown in FIG. 2B, a sensor chip 21 having a sensor region 21a is disposed on a substrate 20 and electrically connected to the substrate 20 via bonding wires 20b. Therein size of the transparent covers 23 corresponds to the sensor chip 21. As shown in FIG. 2C, a transparent cover 23 is disposed on the sensor chip 21, and through a hot pressing process, the dam structure 22 is adhered to the sensor chip 21 and partially covers the bonding wires 20b. As shown in FIG. 2D, the substrate 20 with the transparent cover 23 and the sensor chip 21 is disposed in a package mold and an encapsulant 24 made of such as epoxy resin is filled in the mold and cured, thereby forming a sensor package.

Although size of the transparent cover 23 and width of the whole sensor package are reduced through such a dam structure 22, height of the whole sensor package has almost no change. Thus, the present method still cannot meet demand for thinner sensor packages. In addition, the transfer molding process of the present method increases the fabrication time and cost.

U.S. Pat. No. 6,737,292 discloses a method of attaching an image sensor module to a circuit board, which involves flip-chip electrically connecting a chip to a glass plate predisposed with corresponding conductive bumps, disposing the chip in a cavity of a circuit board, and electrically connecting the circuit board to the corresponding conductive bumps through a conductive adhesive. The present method provides a much thinner sensor package by embedding the chip in the cavity of the circuit board and eliminating the need of spaces for receiving bonding wires. However, the flip-chip process, the process of forming conductive bumps on the glass plate, the special design of the circuit board with cavity as well as the use of additional conductive adhesive complicate the fabrication process, increase the fabrication cost and accordingly prevent practical application of the present method.

Therefore, how to provide a much thinner sensor package and method for fabricating the same that can overcome the above-described drawbacks has become urgent.

### SUMMARY OF THE INVENTION

According to the above drawbacks, an objective of the present invention is to provide a much thinner sensor package and a method for fabricating the same.

Another objective is to provide a sensor package and a method for fabricating the same that eliminate the need of formation of conductive bumps on chips or transparent covers.

A further objective is to provide a sensor package and a method for fabricating the same that eliminate the need of specially designed substrates.

Still another objective is to provide a sensor package and a method for fabricating the same, through which the fabrication process is simplified.

A further objective is to provide a sensor package and a method for fabricating the same that reduce the fabrication difficulty and cost.

To achieve the above and other objectives, the present invention discloses a sensor package, which comprises: a substrate having an opening; a sensor chip disposed in the opening and electrically connected to the substrate through bonding wires, the sensor chip having a sensor region; an encapsulant filling spacing between the sensor chip and the opening so as to secure the sensor chip in the opening; and a transparent cover attached to the substrate via an adhesive layer, wherein the adhesive layer covers the sensor chip and the bonding wires and has an opening for exposing the sensor region.

Therein, the adhesive layer can be disposed at a peripheral region of the transparent cover and enclose the bonding wires, the opening of the adhesive layer is only required to sufficiently expose the sensor region and there is no special limit on the adhesive layer. The transparent cover may be made of glass or acrylic.

The present invention further provides a method for fabricating a sensor package, which comprises: providing a substrate having an opening, a film layer being disposed on the bottom of the substrate so as to seal the bottom of the opening; disposing a sensor chip in the opening of the substrate and electrically connecting the sensor chip to the substrate through bonding wires; the sensor chip having a sensor region; filling with an encapsulant spacing between the sensor chip and the opening and curing the encapsulant so as to secure the sensor chip in the opening and then removing the film layer; and disposing a transparent cover on the substrate, wherein on bottom of the transparent cover there is an adhesive layer that has an opening for exposing the sensor region, the adhesive layer is heated to a melting state so as to cover the sensor chip and the bonding wires, after the adhesive layer is cured, the transparent cover is closely attached to the substrate and seals the sensor region.

The film layer can be a tape or a plastic plate coated with an adhesive, which is removed after the encapsulant is cured. The adhesive layer can be made of an epoxy resin, which is formed on the transparent cover by screen printing or pressing. In one embodiment, the adhesive layer is pre-formed on the transparent cover and has an opening corresponding to the sensor region, the transparent cover with the adhesive layer is disposed on the sensor chip and the substrate with the sensor region exposed through the opening of the adhesive layer.

As the sensor chip is disposed in the opening of the substrate instead of being stacked on the substrate, the height of the sensor package is significantly reduced. Also, the present invention eliminates the need of formation of conductive bumps on the sensor chip or transparent cover, the need of specially designed substrates as well as the need of flip chip process. Accordingly, the fabrication process is simplified and the fabrication difficulty and cost are reduced.

### BRIEF DESCRIPTION OF DRAWINGS

FIG. 1 is a diagram showing a sensor package and method for fabricating the same according to U.S. Pat. No. 6,262,479;

FIGS. 2A to 2D are diagrams showing a sensor package and method for fabricating the same according to U.S. Pat. No. 6,995,462; and

FIG. 3A to 3E are diagrams showing a sensor package and method for fabricating the same according to a preferred embodiment of the present invention.

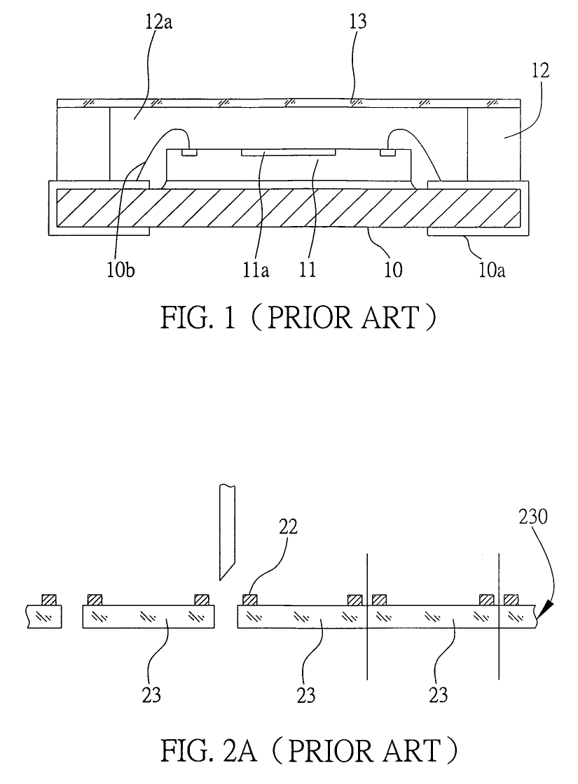

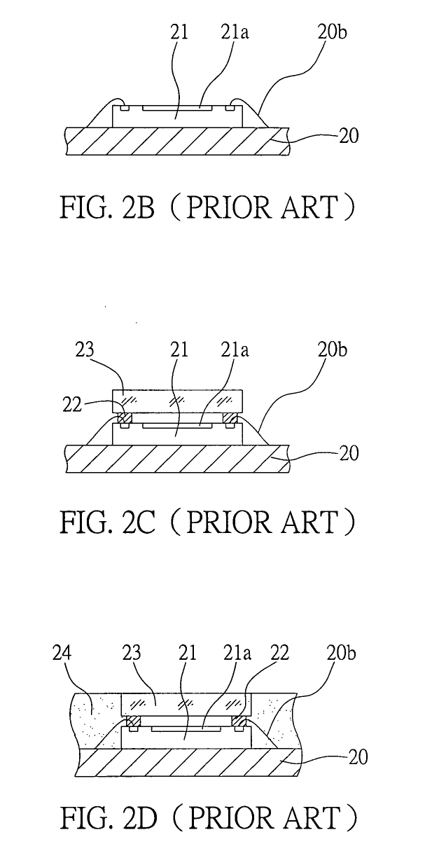

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

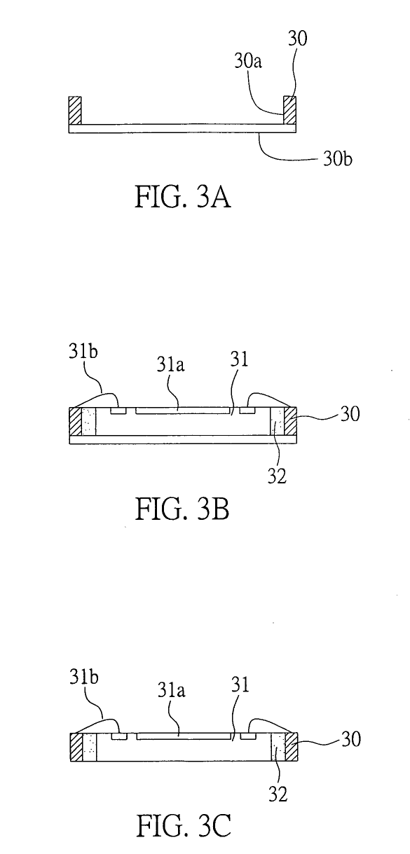

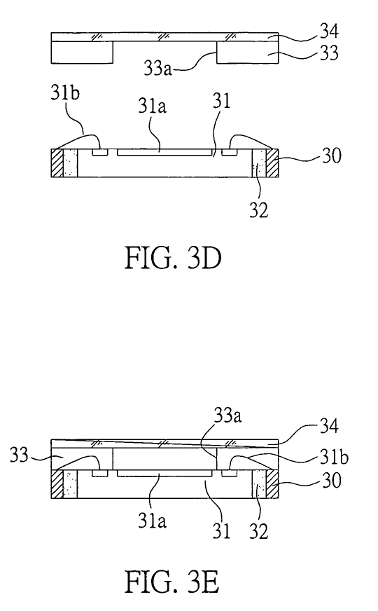

FIGS. 3A to 3E are diagrams showing a method for fabricating a sensor package according to a preferred embodiment of the present invention, wherein substrates, openings, sensor chips, bonding wires, encapsulant, film layers, and adhesive layers are only illustrative to disclose process steps and structural design and do not limit shape, size, or proportion thereof.

As shown in FIG. 3A, a substrate 30 having an opening 30a is provided and a film layer 30b is disposed at the bottom of the substrate 30 for sealing the bottom of the opening 30a. The film layer 30b will be removed in subsequent processes and there is no special limit to the film layer. In the present embodiment, the film layer 30b is a tape. In other embodiments, the film layer 30b can be a plastic plate coated with an adhesive.

As shown in FIG. 3B, a sensor chip 31 having a sensor region 31a is disposed in the opening 30a of the substrate 30 and on the film layer 30b, and an encapsulant 32 is filled in spacing between the sensor chip 31 and the opening 30a of the substrate 30 and cured. Thereafter, the sensor chip 31 is electrically connected to the substrate 30 through bonding wires 31b. In the present embodiment, the encapsulant 32 can be made of a resin compound.

As shown in FIG. 3C, after the encapsulant 32 is cured so as to secure the sensor chip 31 in the opening 30a of the substrate 30, the film layer 30b can be removed, which can be performed before or after wire bonding or performed after the sensor chip is covered by a transparent cover.

As shown in FIG. 3D, a transparent cover 34 made of such as glass is provided. An adhesive layer 33 is pre-formed on the bottom of the transparent cover 34 and the adhesive layer 33 has an opening 33a formed corresponding to the sensor region 31a of the sensor chip 31 such that the sensor region 31a can be exposed through the opening 33a when the transparent cover 34 is disposed on the substrate 30. In the present embodiment, the adhesive layer 33 can be made of an epoxy resin, which is formed around the bottom of the transparent cover 34 by screen printing and has a ring-shaped structure. There is no special limit on size of the adhesive layer 33. In other embodiments, the adhesive layer 33 can be formed on the transparent cover 34 by pressing.

As shown in FIG. 3E, the transparent cover 34 is attached to the substrate 30 via the adhesive layer 33. Through a hot pressing process, the adhesive layer 33 is attached to the substrate 30, the sensor chip 31, and the bonding wires 31b, thereby attaching the transparent cover 34 to the substrate 30 and sealing the substrate 30. Meanwhile, the sensor region 31a is exposed through the opening 33a of the adhesive layer 33 and external light can pass through the transparent cover 34 and captured by the sensor region 31a of the sensor chip 31.

Through the above-described method, a sensor package is obtained as shown in FIG. 3E, which comprises: a substrate 30 having an opening 30a; a sensor chip 31 disposed in the opening 30a and electrically connected to the substrate 30 through bonding wires 31b, the sensor chip 31 having a sensor region 31a; an encapsulant 32 filling spacing between the sensor chip 31 and the opening 30a of the substrate 30 so as to secure the sensor chip 31 in the opening 30a; and a transparent cover 34 attached to the substrate 30 via an adhesive layer 33, wherein the adhesive layer 33 covers the sensor chip 31 and the bonding wires 31b and has an opening 33a for exposing the sensor region 31a of the sensor chip 31.

As the sensor chip 31 is disposed in the opening 30a of the substrate 30 instead of being stacked on the substrate 30, the height of the sensor package is significantly reduced. Also, the present invention eliminates the need of formation of conductive bumps on the sensor chip 31 or transparent cover 34, the need of specially designed substrates as well as the need of flip chip process. Accordingly, the fabrication process is simplified and the fabrication difficulty and cost are reduced.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A sensor package, comprising:
a substrate having an opening;
a sensor chip disposed in the opening and electrically connected to the substrate through bonding wires, the sensor chip having a sensor region;
an encapsulant filling spacing between the sensor chip and the opening so as to secure the sensor chip in the opening; and
a transparent cover attached to the substrate via an adhesive layer, wherein the adhesive layer covers the sensor chip and the bonding wires and has an opening for exposing the sensor region.

2. The sensor package of claim. 1, wherein the encapsulant is made of a resin compound.

3. The sensor package of claim 1, wherein the adhesive layer is made of an epoxy resin.

4. The sensor package of claim 3, wherein the epoxy resin is pre-formed on the bottom of the transparent cover by one of the methods consisting of screen printing and pressing.

5. The sensor package of claim 1; wherein the transparent cover is made of glass.

6. A method for fabricating a sensor package, comprising:
providing a substrate having an opening, a film layer being disposed on the bottom of the substrate so as to seal the bottom of the opening;
disposing a sensor chip in the opening of the substrate and electrically connecting the sensor chip to the substrate through bonding wires; the sensor chip having a sensor region;
filling with an encapsulant spacing between the sensor chip and the opening and curing the encapsulant so as to secure the sensor chip in the opening and then removing the film layer; and
disposing a transparent cover on the substrate, wherein on bottom of the transparent cover there is an adhesive layer that has an opening for exposing the sensor region, the adhesive layer is heated to a melting state so as to cover the sensor chip and the bonding wires, after the adhesive layer is cured, the transparent cover is closely attached to the substrate and seals the sensor region.

7. The method of claim 6, wherein the film layer is one of a tape and a plastic plate coated with an adhesive.

8. The method of claim 6, wherein the encapsulant is made of a resin compound.

9. The method of claim 6, wherein the adhesive layer is pre-formed on the transparent cover and has an opening corresponding to the sensor region, the transparent cover with the adhesive layer is disposed on the sensor chip and the substrate with the sensor region exposed through the opening of the adhesive layer.

10. The method of claim 6, wherein the adhesive layer is made of an epoxy resin.

11. The method of claim 10, wherein the adhesive layer is formed by one of the methods consisting of screen printing and pressing.

12. The method of claim 6, wherein the transparent cover is made of glass.
